(19) United States
(12) Patent Application Publication
(10) Pub. No.: US 2026/0042981 A1
(43) Pub. Date: Feb. 12, 2026

(54) CLEANING SLURRY FOR SEMICONDUCTOR DEVICE AND METHOD OF MANUFACTURING SEMICONDUCTOR DEVICE

(71) Applicant: SAMSUNG ELECTRONICS CO., LTD., Suwon-si (KR)

(72) Inventors: Fedosya KALININA, Suwon-si (KR); YOUNHWA KANG, Suwon-si (KR); Jung Hoon LEE, Suwon-si (KR); Sang Soo JEE, Suwon-si (KR); Yoonseok KO, Suwon-si (KR); Hyune Jea LEE, Suwon-si (KR)

(21) Appl. No.: 19/283,897

(22) Filed: Jul. 29, 2025

(30) Foreign Application Priority Data
Aug. 7, 2024 (KR) 10-2024-0105710

(51) Int. Cl. C11D 17/00; C09G 1/02; C09K 3/14; C11D 7/26; C11D 7/32; C11D 7/34; H01L 21/02; H01L 21/306; H01L 21/3105; H01L 21/321

(52) U.S. Cl. CPC C11D 17/0013; C09G 1/02; C09K 3/1409; C11D 7/267; C11D 7/3281; C11D 7/34; H01L 21/0206; H01L 21/02068; H01L 21/30625; H01L 21/31053; H01L 21/3212

(57) ABSTRACT

A method of manufacturing a semiconductor device includes performing chemical mechanical polishing on a surface using a polishing slurry including abrasives, and first cleaning by supplying a cleaning slurry including soft particles and a dispersion medium to remove the abrasives from a polished surface on which the chemical mechanical polishing is performed he soft particles having a lower hardness than the polished surface, wherein a zeta potential of one of the soft particles and the abrasives at a pH of the cleaning slurry is greater than 0, and a zeta potential of the other of the soft particles and the abrasives at the pH of the cleaning slurry is less than 0.

### CROSS-REFERENCE TO RELATED APPLICATION

This application is based on and claims priority to Korean Patent Application No. 10-2024-0105710, filed in the Korean Intellectual Property Office on Aug. 7, 2024, and all the benefits accruing therefrom under 35 U.S.C. § 119, the content of which is incorporated herein by reference in its entirety.

### BACKGROUND

### 1. Field

The present disclosure relates to a cleaning slurry for a semiconductor device and a method of manufacturing a semiconductor device including the cleaning slurry for the semiconductor device.

### 2. Description of the Related Art

Recently, due to the miniaturization of electronic devices and the subsequent miniaturization of integrated circuits, various methods of forming microstructures such as metal wiring with a width of several nanometers or narrow trench isolation have been studied.

In forming such microstructures, in order to create a flat surface of the microstructures, a polishing process such as a chemical mechanical polishing (CMP) process may be performed. The chemical mechanical polishing process is a process of providing a polishing slurry including abrasives between a semiconductor substrate (including a thin film such as a dielectric layer and/or a metal layer) and a polishing pad and then contacting the semiconductor substrate with the polishing pad to planarize, i.e., polish, the surface of the semiconductor substrate. After the CMP process, a cleaning process is then required to remove any remaining abrasives and polishing by-products.

### SUMMARY

Recently, fine abrasives with a size of several to tens of nanometers has been used to effectively perform the chemical mechanical polishing process on the microstructures. However, such fine abrasives may be attached on the surface of the semiconductor substrate even after the chemical mechanical polishing process and not easily removed. The fine abrasives that are not removed in this way may cause defects on the semiconductor substrate, thereby affecting productivity of the semiconductor device.

An embodiment provides a method for manufacturing a semiconductor device capable of effectively removing fine abrasives used in the chemical mechanical polishing process.

Another embodiment provides a cleaning slurry for a semiconductor device capable of effectively removing fine abrasives used in the chemical mechanical polishing process.

According to an embodiment, a method of manufacturing a semiconductor device includes performing a chemical mechanical polishing process on a surface of the semiconductor device using a polishing slurry including abrasives to provide a polished surface, and conducting a cleaning by supplying a cleaning slurry including soft particles and a dispersion medium to remove the abrasives from the polished surface on which the chemical mechanical polishing process is performed, the soft particles having a lower hardness than the polished surface. A zeta potential of one of the soft particles and the abrasives at a pH of the cleaning slurry is greater than 0, and a zeta potential of the other of the soft particles and the abrasives at the pH of the cleaning slurry is less than 0.

A difference between a zeta potential of the abrasives and a zeta potential of the soft particles at the pH of the cleaning slurry may be greater than or equal to about 20 millivolts (mV).

A zeta potential of the soft particles at the pH of the cleaning slurry may be about −10 mV to about −140 mV.

A zeta potential of the abrasives at the pH of the cleaning slurry may be about +10 mV to about +140 mV.

The pH of the cleaning slurry may be in the range of about 2 to about 6.5.

The polished surface may include an oxide, a nitride, a carbide, a semiconductor elementary substance, a semiconductor compound, an organic-inorganic compound, a metal, a metal alloy, or a combination thereof.

The abrasives may include fine abrasives having a particle diameter (also referred to as particle size) of greater than or equal to about 1 nanometers (nm) and less than about 50 nm. A particle size of the soft particles may be greater than that of the fine abrasives.

The abrasives may include oxide abrasives, nitride abrasives, carbon abrasives, or a combination thereof.

The abrasives may include ceria abrasives.

The dispersion medium may include water.

The method may further include an additional cleaning for removing polishing by-products from the polished surface, and the additional cleaning may include supplying a chemical solution for removing the polishing by-product from the polished surface, and contacting the polished surface with a cleaning brush or supplying an ultrasonic wave to the polished surface, each in the presence of the chemical solution for removing the polishing by-product.

According to another embodiment, a method of manufacturing a semiconductor device includes performing a chemical mechanical polishing process on a surface of the semiconductor device using a polishing slurry including abrasives to provide a polished surface, supplying a first cleaning slurry to the polished surface on which the chemical mechanical polishing is performed to remove the abrasives from the polished surface, and supplying a second chemical solution to the polished surface with the abrasives removed, on which the chemical mechanical polishing is performed and contacting the polished surface with a cleaning brush or supplying an ultrasonic wave to the polished surface, each in the presence of the second chemical solution. The abrasives include fine abrasives having a particle diameter of greater than or equal to about 1 nm and less than about 50 nm. The cleaning slurry includes soft particles and a dispersion medium. A hardness of the soft particles is lower than that of the polished surface, and a particle size of the soft particles is greater than that of the fine abrasives.

The soft particles may include an organic material, an inorganic material, an organic-inorganic material, or a combination thereof, having negative or positive surface charges.

The soft particles may include polymer beads having negative or positive surface charges.

The soft particles may include hexagonal boron nitride.

According to another embodiment, a cleaning slurry for a semiconductor device, which may be applied after a chemical mechanical polishing using a polishing slurry comprising abrasives, includes soft particles including organic material, inorganic material, organic-inorganic material or a combination thereof, and having a zeta potential of about −10 mV to about −140 mV at the pH of the cleaning slurry, and a dispersion medium.

A Mohs Hardness of the soft particles may be about 1 to about 5.

The particle diameter of the soft particles may be about 30 nm to about 2 micrometers (μm).

The pH of the cleaning slurry may be about 2 to about 6.5.

The cleaning slurry for a semiconductor device may further include a pH adjuster.

An amount of the soft particles may be about 0.01 to about 5 weight percent (wt %) based on the cleaning slurry.

By effectively removing abrasives (fine abrasives) remaining after chemical mechanical polishing process, it is possible to effectively reduce or prevent defects in semiconductor devices and reduced productivity caused by the remaining abrasives (fine abrasives).

### BRIEF DESCRIPTION OF THE DRAWINGS

FIG. 1 is a graph showing the zeta potential (millivolts, mV) according to a pH of the soft particles according to Synthesis Examples and Comparative Synthesis Examples,

FIG. 2 is a scanning electron microscope (SEM) photograph of the soft particles obtained in Synthesis Example 1 before mixing with ceria abrasive,

FIG. 3 is a SEM photograph showing the soft particles obtained in Synthesis Example 1 and the ceria abrasives adsorbed thereon after mixing them,

FIG. 4 is a SEM photograph of the soft particles obtained in Synthesis Example 2 before mixing with ceria abrasive, and

FIG. 5 is an SEM photograph showing the soft particles obtained in Synthesis Example 2 with the ceria abrasives adsorbed thereon after mixing the soft particles and the ceria abrasive.

### DETAILED DESCRIPTION

Hereinafter, the embodiments will be described in detail so that those of ordinary skill in the art may easily implement them. However, the actually applied structure may be implemented in several different forms and is not limited to the embodiments described herein.

As used herein, when a definition is not otherwise provided, “substituted” refers to replacement of hydrogen of a compound or a functional group by a substituent selected from a halogen atom, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a silyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As used herein, “substantially” and “about” include an approximate range considering variations and errors within a normal range, for example, about ±5%, ±4%, ±3%, ±2%, or ±1%.

Hereinafter, the term “combination” includes a mixture, or a stacked structure of two or more.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. All ranges recited herein are inclusive of the endpoints.

Hereinafter, a cleaning slurry for a semiconductor device according to an embodiment is described.

The cleaning slurry for a semiconductor device may be used to clean a solid surface, such as a surface of a semiconductor substrate (including a thin film such as a dielectric layer or a metal layer) in a semiconductor device manufacturing process, and may be used to remove residual abrasives on a polished surface after chemical mechanical polishing (hereinafter, referred to as the “CMP”) process using abrasives.

A cleaning slurry for a semiconductor device according to an embodiment includes soft particles and a dispersion medium.

The soft particles may be particles having relatively low hardness, for example, spherical, sheet-shaped, linear, irregular, and/or amorphous particles having a lower hardness than the solid surface (e.g., a polished surface) to be cleaned.

For example, the soft particles may have a lower hardness than the polished surface on which a CMP process is performed. Herein, the polished surface may include an oxide such as silicon oxide or aluminum oxide; a nitride such as silicon nitride, aluminum nitride, titanium nitride or gallium nitride; a carbide such as silicon carbide; a semiconductor elementary substance (also referred to as an elemental semiconductor) such as silicon or germanium; a semiconductor compound (also referred to as a compound semiconductor) such as InP or GaAs; an organic-inorganic compound such as tetraethyl orthosilicate (TEOS); a metal such as aluminum, copper, molybdenum or nickel, an alloy thereof or a metal oxide or metalloid oxide generated during a CMP process; or a combination thereof, and the Mohs Hardness of the polished surface may be in the range of about 5 to about 10. The Mohs Hardness of the soft particles may be lower than the Mohs Hardness of the polished surface, for example, from about 1 to about 5, and within this range about 1 to about 4, about 1 to about 3, or about 1 to about 2. Accordingly, when the soft particles come into contact with the polished surface, damages such as scratches may not occur to the polished surface.

The soft particles may be larger than at least a portion of the abrasives (hereinafter, referred to as an ‘abrasives’) used for the CMP process. The abrasives may have various sizes, for example, a particle diameter (e.g., an average particle diameter) ranging from about 1 nm to about 150 nm.

The abrasives may include, for example, fine abrasives with a particle size of greater than or equal to about 1 nm to less than about 50 nm, for example, about 5 nm to less than about 45 nm, about 10 nm to less than about 40 nm, or about 15 nm to less than about 35 nm, and the soft particles may be larger than the fine abrasives. The fine abrasives may be, for example, oxide abrasives, nitride abrasives, carbon abrasives, or a combination thereof, for example, ceria abrasives, silica abrasives, silicon nitride abrasives, SiC, diamond, fullerene, a fullerene derivative, or a combination thereof, but is not limited thereto. For example, a particle diameter (including a major diameter) of the soft particles may be at least twice as large as that of the fine abrasives and within the ranges, for example about 2 times to about 2000 times, about 5 times to about 200 times, about 10 times to about 100 times, about 15 times to about 50 times, or about 20 times to about 30 times, as large as that of the fine abrasives.

The particle diameter of the soft particles may be, for example, about 30 nm to about 2 μm, about 50 nm to about 1500 nm, about 60 nm to about 1200 nm, about 80 nm to about 1000 nm, or about 100 nm to about 500 nm within the larger ranges than that of the fine abrasives. Herein, the particle diameter may be an average particle diameter of the particles, which is measured by using dynamic light scattering (DLS). In this way, the larger soft particles than the abrasives (fine abrasives) are supplied for cleaning after the CMP process to physically detach the abrasives (fine abrasives) from the polished surface.

The soft particles may be charged in the cleaning slurry and thus may have negative or positive surface charges. Surface charges of the soft particles may have an opposite sign to that of a surface charge of a target object to be removed by the cleaning slurry, for example, the abrasives (e.g., fine abrasives). For example, if the abrasives have positive surface charges, the soft particles may have negative surface charges. For example, if the abrasives have negative surface charges, the soft particles may have positive surface charges. In this way, if the soft particles have an opposite surface charge to the abrasives, an electrostatic attractive force may effectively act between the soft particles and the abrasives, without a surfactant, to effectively prevent reattachment of the abrasives separated from the polished surface onto the polished surface and effectively adsorb it on the soft particles.

The surface charges may be evaluated by a zeta potential. The zeta potential represents an electrostatic potential on the particle surface at a predetermined pH, confirming types and amounts of charges on particles. The zeta potential may be measured by using electrophoretic mobility through electrophoresis.

The zeta potential may vary depending on a pH. At a predetermined pH (e.g., process pH or pH of the cleaning slurry), the soft particles have a zeta potential with an opposite sign to that of a zeta potential of the abrasive, thereby securing an electrostatic attractive force between the abrasives and the soft particles. For example, the process pH or the pH of the cleaning slurry may be about 2 to about 12, and within the range, about 2 to about 10, about 2 to about 8, about 2 to about 6.5, about 2 to about 6, about 3 to about 6.5, about 3 to about 6, about 3.5 to about 6.5, about 3.5 to about 6, or about 3.5 to about 5.5. For example, the process pH or the pH of the cleaning slurry may be about 2 to about 6.

For example, at the pH of the cleaning slurry, the soft particles and the abrasives may maintain each zeta potential with an opposite sign. For example, at the pH of the cleaning slurry, a zeta potential of one of the soft particles and the abrasives may be larger than about 0, and zeta potential of the other of the soft particles and the abrasives may be smaller than about 0. In other words, according to a zeta potential of the abrasives at the pH of the cleaning slurry, the soft particles having a smaller zeta potential than 0 or a larger zeta potential than 0 may be selected, provided that the sign of the zeta potential of the soft particles is opposite to that of the zeta potential of the abrasives.

For example, the zeta potential of the abrasives at the pH of the cleaning slurry may be greater than 0, and the zeta potential of the soft particles at the pH of the cleaning slurry may be less than 0. For example, the zeta potential of the ceria (i.e., cerium oxide) abrasives at the pH of the cleaning slurry may be greater than 0, and the zeta potential of the soft particles at the pH of the cleaning slurry may be less than 0. For example, when using ceria abrasives, the zeta potential of the ceria abrasives at the pH of the cleaning slurry may be about +10 mV to about +140 mV, and the zeta potential of the soft particles at the pH of the cleaning slurry may be about −10 mV to about −140 mV. Within the above range, the zeta potential of the ceria abrasives at the pH of the cleaning slurry may be about +20 mV to about +140 mV, about +20 mV to about +120 mV, about +30 mV to about +120 mV, about +40 mV to about +110 mV, or about +50 mV to about +100 mV, or about +60 mV to about +90 mV, and the zeta potential of the soft particles at the pH of the cleaning slurry may be about −20 mV to about −140 mV, about −20 mV to about −120 mV,-30 mV to about −120 mV, about −10 mV to about −100 mV, about −10 mV to about −90 mV, or about −20 mV to about −80 mV.

For example, a difference between the zeta potential of the abrasives and the zeta potential of the soft particles at the pH of the cleaning slurry may be greater than or equal to about 20 mV, and within this range about 20 mV to about 280 mV, about 30 mV to about 280 mV, about 40 mV to about 280 mV, about 50 mV to about 280 mV, about 60 mV to about 280 mV, about 20 mV to about 240 mV, about 30 mV to about 240 mV, about 40 mV to about 240 mV, about 50 mV to about 240 mV, about 60 mV to about 240 mV, about 70 mV to about 220 mV, about 80 mV to about 200 mV, or about 90 mV to about 180 mV. By having a zeta potential difference between the abrasives and the soft particles within the ranges, there may be a much stronger electrostatic attractive force between the abrasives and the soft particles, more effectively preventing reattachment of the abrasives separated from the polished surface onto the polished surface and effectively adsorbing the abrasives onto the soft particles.

In this way, the soft particles in the cleaning slurry may physically detach the abrasives (fine abrasives) remaining on the polished surface after the CMP process and simultaneously, preventing reattachment of the abrasives onto the polished surface and effectively adsorbing the abrasives on the soft particles by the electrostatic attractive force.

Accordingly, the abrasives (fine abrasives) remaining after the CMP process may be removed to prevent defects of a semiconductor device, and a decrease in productivity of the semiconductor device caused by residual abrasives (fine abrasives) may be prevented. In addition, the abrasives (e.g., fine abrasives) may be effectively removed from the polished surface without a separate surfactant in the cleaning slurry, and thus may prevent any influence on the semiconductor device due to a residual surfactant remaining during the cleaning, in contrast to a cleaning slurry including a surfactant. Use of the cleaning slurry with no surfactant is advantageous because it needs no additional process for removing the surfactant, thereby simplifying the cleaning process.

For example, if fine ceria abrasives with a particle diameter of less than about 50 nm is used in the CMP process to polish the silicon oxide surface, since strong Ce—O—Si bonds may be formed on the polished surface, the fine ceria abrasives may not be easily removed from the polished surface, and so, in order to remove this fine ceria abrasives, chemical cleaning with strong acid such as sulfuric acid and/or physical cleaning may be required.

On the contrary, the aforementioned cleaning slurry may effectively remove the Ce—O—Si bonds from the polished surface by contacting the soft particles having a larger size than the fine ceria abrasives, with the fine ceria abrasives, to effectively detach the fine ceria abrasives from the polished surface and simultaneously, prevent reattachment of the fine ceria abrasives to the polished surface by an electrostatic attractive force and effectively adsorb the fine ceria abrasives on the soft particles. Accordingly, the fine ceria abrasives may be effectively removed from the polished surface without a separate surfactant in the cleaning slurry.

The soft particles may include an organic material, an inorganic material, an organic-inorganic material, or a combination thereof, having negative or positive surface charges. The soft particles may include an organic material, an inorganic material, an organic-inorganic material, or a combination thereof, which exhibits the aforementioned zeta potential at a predetermined pH (process pH or pH of a cleaning slurry). For example, the soft particles may include polymer particles having the above characteristics, for example, spherical polymer beads.

The polymer particles may include crosslinked or non-crosslinked polymers having negative or positive surface charges in a dispersion medium (e.g., a liquid such as water). The crosslinked or non-crosslinked polymer, as described above, may have negative or positive surface charges in the dispersion medium (e.g., water) and may include a functional group determining the surface charges to secure such electric characteristics. For example, the crosslinked or non-crosslinked polymer having negative surface charges may include a carboxylic acid group, a sulfonic acid group, a phosphoric acid group, a phosphonic acid group, a salt derived therefrom, or a combination thereof at the terminal end, but is not limited thereto. For example, the crosslinked or non-crosslinked polymer having a positive surface charges may include a primary, secondary, or tertiary amine group, an amidine group, a trialkyl amine group, e.g., a tri(C1-C12 alkyl)amine group, a salt derived therefrom, or a combination thereof at the terminal end, but is not limited thereto. The polymer particles may include, for example, a polymer having the above-described electrical characteristics while including a styrene structural unit (i.e., a styrene repeating unit) including a carboxylic acid group, a sulfonic acid group, a phosphoric acid group, a phosphonic acid group, and/or a salt derived therefrom as the functional group at the terminal end, but is not limited thereto. For example, the polymer particles may include, for example, a maleic anhydride structural unit (i.e., a maleic anhydride repeating unit), an itaconic anhydride structural unit (i.e., an itaconic anhydride repeating unit), a citraconic (methylmaleic) anhydride structural unit (i.e., a citraconic anhydride repeating unit) and other substituted anhydrides whose anhydride groups are partially or fully converted into a carboxylic acid group and/or a salt thereof.

As described above, the polymer particles may have a zeta potential less than 0 at the pH of the cleaning slurry. For example, the polymer particles may have a zeta potential greater than 0 at the pH of the cleaning slurry. For example, the zeta potential of the polymer particles at pH of the cleaning slurry may be about −10 mV to about −140 mV, and within that range about −20 mV to about −140 mV, about −20 mV to about −120 mV, about −30 mV to about −120 mV, about −10 mV to about −100 mV, about −10 mV to about −90 mV, or about −20 mV to about −80 mV. For example, a difference between the zeta potential of the abrasives and the zeta potential of the polymer particles at the pH of the cleaning slurry may be greater than or equal to about 20 mV, and within this range about 20 mV to about 280 mV, about 30 mV to about 280 mV, about 40 mV to about 280 mV, about 50 mV to about 280 mV, about 60 mV to about 280 mV, about 20 mV to about 240 mV, about 30 mV to about 240 mV, about 40 mV to about 240 mV, about 50 mV to about 240 mV, about 60 mV to about 240 mV, about 70 mV to about 220 mV, about 80 mV to about 200 mV, or about 90 mV to about 180 mV.

The polymer particles may be synthesized by various synthetic methods without a separate surfactant, for example, by a soap-free emulsion polymerization, a suspension polymerization, or a precipitation polymerization.

For example, the soft particles may include an inorganic material having the aforementioned characteristics, such as an oxide, a nitride, an oxynitride, or a combination thereof having the aforementioned characteristics. For example, the soft particles may include hexagonal boron nitride, but are not limited to.

The soft particles may be included in an amount of less than or equal to about 5 wt % based on the total weight of the cleaning slurry, and within this range about 0.01 to about 5 wt %, about 0.1 to about 5 wt %, about 0.1 to about 3 wt %, about 0.1 to about 2 wt %, about 0.2 to about 2 wt %, about 0.3 to about 2 wt %, or about 0.4 to about 2 wt %, each based on the total weight of the cleaning slurry.

The cleaning slurry for a semiconductor device may further include a pH adjuster. The pH adjuster may adjust the pH of the cleaning slurry, for example, the pH of the cleaning slurry may be adjusted to about 2 to about 12, and within this range, about 2 to about 10, about 2 to about 8, about 2 to about 6.5, about 2 to about 6, about 3 to about 6.5, about 3 to about 6, about 3.5 to about 6.5, about 3.5 to about 6, or about 3.5 to about 5.5.

The pH adjuster may be, for example, an inorganic acid, an organic acid, an inorganic base, an organic base, a salt thereof, or a combination thereof. The inorganic acid may include, for example, nitric acid, hydrochloric acid, phosphoric acid, sulfuric acid, hydrofluoric acid, hydrobromic acid, iodic acid or salts thereof, the organic acid may include, for example, formic acid, malonic acid, maleic acid, oxalic acid, adipic acid, citric acid, acetic acid, propionic acid, fumaric acid, lactic acid, salicylic acid, benzoic acid, succinic acid, phthalic acid, butyric acid, glutaric acid, glutamic acid, glycolic acid, lactic acid, aspartic acid, tartaric acid or salts thereof, and the inorganic base may include, for example, NaOH, KOH, or a combination thereof, but are not limited thereto. The pH adjuster may be included in a small amount in the cleaning slurry, for example, about 1 parts per million (ppm) to about 100,000 ppm based on the cleaning slurry.

The cleaning slurry for a semiconductor device may not include a surfactant. As described above, since the soft particles may physically detach the abrasives (fine abrasives) remaining on the polished surface and simultaneously prevent the abrasives from reattaching onto the polished surface by electrostatic attraction and effectively adsorb it to the soft particles, the cleaning slurry may not include a separate surfactant.

The dispersion medium may be, for example, water. The water may be, for example, distilled water and/or deionized water. The dispersion medium may be included as a balance amount excluding solid particles such as soft particles and the pH adjuster.

The aforementioned cleaning slurry may be used in a cleaning process after a CMP process. The aforementioned cleaning slurry may be used prior to a post-chemical mechanical polishing cleaning (post-CMP cleaning) process in which physical cleaning and chemical cleaning are performed simultaneously. For example, the aforementioned cleaning slurry may be applied in a buff cleaning between a CMP process and a post-CMP cleaning process. That is, by simply supplying the aforementioned cleaning slurry in the buff cleaning, residual fine abrasives such as fine ceria abrasives may be effectively removed without physical cleaning using a cleaning brush or ultrasonic waves or chemical cleaning using a chemical solution, unlike the post-CMP cleaning.

An example of a method for manufacturing a semiconductor device including the cleaning process described below is described.

A method for manufacturing a semiconductor device according to an embodiment includes performing a CMP process on a surface of an object to be polished, and supplying a cleaning slurry including the aforementioned soft particles and a dispersion medium to the polished surface to clean it.

The object to be polished may be a variety of structures, for example, a semiconductor substrate such as a silicon wafer (including a thin film such as a dielectric layer or a metal layer), and the polished surface may include an oxide such as silicon oxide or aluminum oxide; a nitride such as silicon nitride, aluminum nitride, titanium nitride or gallium nitride; a carbide such as silicon carbide; an elemental semiconductor such as silicon or germanium; a compound semiconductor such as InP or GaAs; an organic or inorganic compound such as tetraethylorthosilicate (TEOS); a metal such as aluminum, copper, molybdenum or nickel, an alloy thereof, or a metal oxide or a semi-metal oxide generated during a CMP process; or a combination thereof. For example, the polished surface may include a conductor such as a metal wire, or an insulator such as a shallow trench isolation (STI) element or an insulating film, and for example, the polished surface may include silicon oxide and/or silicon nitride.

The CMP process may be performed using chemical mechanical polishing (CMP) equipment. The CMP equipment may include, for example, a lower base; a platen rotatably provided on an upper surface of the lower base; a polishing pad on the platen; a pad conditioner; and a polishing slurry nozzle adjacent to the polishing pad for supplying polishing slurry to the polishing pad.

The platen may be provided rotatable on the surface of the lower base. For example, the platen may receive rotational power from a motor disposed in the lower base. Accordingly, the platen may rotate around an imaginary rotation axis perpendicular to the surface of the platen. The imaginary rotation axis may be perpendicular to the surface of the lower base.

A polishing pad may be disposed on the surface of the platen to be supported by the platen. The polishing pad may be rotated with the platen. The polishing pad may have a rough polishing surface. These polishing surfaces may directly contact the object to be polished, such as a semiconductor substrate, to mechanically polish the surface of the object to be polished. The polishing pad may include a porous material having a plurality of micropores (microspaces) and the plurality of micropores may be capable of receiving a polishing slurry. The pad conditioner may be placed adjacent to the polishing pad and may maintain the condition of the polishing pad constant while the polishing process is performed.

The polishing slurry nozzle may be placed adjacent to the polishing pad, and the polishing slurry may be supplied to the polishing pad. The polishing slurry nozzle may further include a voltage supply unit capable of applying a predetermined voltage. The polishing slurry in the nozzle may be charged by a voltage applied from the voltage supply unit and discharged toward the polishing pad.

The CMP process may be, for example, performed by placing an object to be polished such as a semiconductor substrate and the polishing pad facing each other, supplying the polishing slurry from the polishing slurry nozzle between the object to be polished and the polishing pad, and contacting the surface of the object to be polished with the polishing pad.

The polishing slurry may include abrasives and a dispersion medium. The abrasives may have various sizes, for example, an average particle diameter of about 1 nm to about 150 nm. The abrasives may include, for example, fine abrasives with a particle diameter of greater than or equal to about 1 nm and less than about 50 nm. The fine abrasives may include, for example, oxide abrasives, nitride abrasives, carbon abrasives, or a combination thereof. The oxide abrasives may include, for example, ceria abrasives. The nitride abrasives may include, for example, silicon nitride abrasives. The carbon abrasives may be two- or three-dimensional polishing particles made of or containing carbon, for example, SiC, diamond and/or fullerene (e.g., C60, C70, C74, C76, or C78) or a fullerene derivative. The polishing slurry may further include an additive, wherein the additive may include, for example, a chelating agent, an oxidizing agent, a surfactant, a dispersant, a pH adjuster, or a combination thereof, but is not limited thereto. The dispersion medium may be water, for example, distilled water and/or deionized water.

The polishing slurry may be supplied at a flow rate of about 10 milliliters per minute (ml/min) to about 300 ml/min, and the total amount of the polishing slurry applied may be, for example, about 10 milliliters to about 500 milliliters.

The CMP process may be performed through mechanical friction by bringing an object to be polished such as a semiconductor substrate with the surface of the polishing pad and rotating them. For example, during the CMP process, a pressure of about 1 pounds per square inch (psi) to about 5 psi may be applied thereto.

After the CMP process, the polished surface may be cleaned using the cleaning slurry including the soft particles as described herein (referred to herein as a “first” cleaning). The first cleaning may be a separate process from a post-CMP cleaning, which is cleaning after the CMP process that requires physical cleaning using a cleaning brush or an ultrasonic wave and chemical cleaning using a chemical solution, and performed to effectively remove the abrasives (fine abrasives) remaining on the polished surface after the CMP process.

The first cleaning with the cleaning slurry may be performed, for example, in the buff cleaning step. While the conventional buff cleaning is a process of removing contaminants from the polished surface by supplying water (distilled water and/or deionized water) to the polishing surface, which is heavily contaminated, the cleaning with the chemical slurry may be performed by supplying (e.g., spraying) the cleaning slurry including the soft particles and the dispersion medium instead of the water (distilled water and/or deionized water). Accordingly, the first cleaning in which the aforementioned cleaning slurry is supplied to clean the polished surface may be performed not as an additional process but within the conventional process. The cleaning with the cleaning slurry may be performed, for example, after the CMP process but before the post-CMP cleaning (i.e., additional or second cleaning).

The cleaning with the cleaning slurry may be performed by supplying the aforementioned cleaning slurry onto the polished surface which is completed with the CMP process. The cleaning slurry may be supplied through the above polishing slurry nozzle or a separate nozzle.

As described above, the aforementioned cleaning slurry may include the soft particles having a larger size than the abrasives (fine abrasives) and the predetermined electric characteristics, wherein the soft particles may be in contact with the abrasives to effectively detach the abrasives from the polished surface and simultaneously, prevent reattachment of the abrasives (fine abrasives) to the polished surface and effectively adsorbing the abrasives (fine abrasives) onto the soft particles by an electrostatic attractive force between the soft particles and the abrasives (fine abrasives). Accordingly, the abrasives (fine abrasives) may be effectively removed from the polished surface without a separate surfactant in the cleaning slurry. Specific description of the cleaning slurry is the same as described above.

After the cleaning with the cleaning slurry, a post-CMP cleaning (additional or second cleaning) may be performed. The post-CMP cleaning (second cleaning) may remove a polishing by-product (e.g., oxide, nitride, carbide, semiconductor elementary substance, semiconductor compound, organic/inorganic compound, or residue of metal and/or the metal alloy) remaining on the polished surface after the CMP process through physical cleaning using a cleaning brush or an ultrasonic wave and chemical cleaning using a chemical solution.

For example, the post-CMP cleaning (second cleaning) may include supplying a chemical solution for removing the polishing by-product from the polished surface, contacting the cleaning brush with the polished surface or supplying the ultrasonic wave onto the polished surface, and optionally, drying and/or heating it. The supplying the chemical solution and the contacting the cleaning brush onto the polished surface or the supplying the ultrasonic wave with the polished surface may be simultaneously or sequentially performed.

The chemical solution may include, for example, an organic material including a functional group configured to form a chemical bond (e.g., a coordination bond, a hydrogen bond, and/or an ion bond) with the polishing by-product, a surfactant, and a solvent.

The cleaning brush may have a cylindrical main body capable of rotating in a predetermined direction and a plurality of protrusions. The cylindrical main body may be fitted onto a predetermined rotation axis (not shown) and contact the polished surface, while rotating in any direction such as a clockwise or counterclockwise direction. The plurality of protrusions may increase a frictional force between the cleaning brush and the polished surface during the rotation of the cleaning brush to effectively separate the polishing by-product on the polished surface from the polished surface. The cleaning brush may include a polymer, for example, a porous polymer that does not damage the polished surface (e.g., the surface of a semiconductor substrate) but well absorbing or discharging a liquid such as water or a cleaning solution, wherein the porous polymer may include, for example, a polyvinyl alcohol (PVA)-based polymer, a polyurethane (PU)-based polymer, or a combination thereof, but is not limited thereto.

The drying and/or the heating may be performed at a temperature, for example, about 25° C. to about 200° C., which may dry the chemical solution remaining on the polished surface by blowing air, etc. and simultaneously, enhance performance of the physical cleaning and/or chemical cleaning.

Hereinafter, the embodiments are illustrated in more detail with reference to examples. However, these examples are exemplary, and the present scope is not limited thereto.

### SYNTHESIS EXAMPLES

### Synthesis Example 1

1 gram (g) of sodium styrene sulfonate is charged into a double-walled glass reactor equipped with a mechanical stirrer, an N₂ inlet, and a reflux condenser and then dissolved in 880 milliliters (ml) of deionized water to prepare a solution. Subsequently, the solution is heated up to about 70° C. and purged with N₂, and then 100 g of styrene and 1 g of potassium persulfate are added thereto. The solution is polymerized at 70° C. for 18 hours under an N₂ atmosphere to obtain a soft particle dispersion. After the polymerization reaction, the soft particle dispersion is filtered through a glass filter to obtain soft particles.

### Synthesis Example 2

7.35 g of maleic anhydride, 6.51 g of divinylbenzene, 0.28 g of 2,2-azobis-isobutyronitrile (AIBN), 250 ml of butylacetate, and 125 ml of heptane are charged into a 500 ml three-necked flask equipped with an N₂ inlet and a reflux condenser to prepare a solution. After dissolving all the reactants, the solution is purged with N₂, and the flask is placed in an oil bath at 90° C. for 2 hours for polymerization. After the polymerization reaction, soft particles are separated by centrifugation and then, washed with butyl acetate and petroleum ether. Then, the product therefrom is dried under vacuum overnight. An anhydride functional group thereof is hydrolyzed to acidic groups through sodium salt by using sodium hydroxide and hydrochloric acid. The finally obtained soft particles are washed several times with water and ethanol and then, dried under vacuum to obtain soft particles.

### Synthesis Example 3

Soft particles are synthesized in the same manner as in Synthesis Example 1 except that 0.07 g of the sodium styrene sulfonate is used instead of 1 g of the sodium styrene sulfonate.

### Synthesis Example 4

2.93 g of maleic anhydride, 2.49 g of triallyl isocyanurate, 0.16 g of 2,2-azobis-isobutyronitrile (AIBN), 13 g of isoamylacetate, and 8.7 g of cyclohexane are charged into a 100 ml three-necked flask equipped with an N₂ inlet and a reflux condenser to prepare a solution. After dissolving all the reactants, the solution is purged with N₂, and a flask is placed in an oil bath at 75° C. for 5 hours for polymerization. After the polymerization reaction, soft particles are separated by centrifugation and then, washed with isoamyl acetate and petroleum ether. Subsequently, a product therefrom is dried under vacuum overnight. Anhydride functional groups thereof are changed to sodium maleate groups through a reaction with sodium hydroxide. The finally obtained soft particles are washed several times with water and ethanol and then, dried under vacuum to obtain soft particles.

### Comparative Synthesis Example 1

1.008 g of (vinylbenzyl) trimethylammonium chloride is charged into a double-walled glass reactor equipped with a mechanical stirrer, an N₂ inlet, and a reflux condenser, and then, is dissolved in 720 mL of deionized water to prepare a solution. Subsequently, the solution is heated to 65° C. and purged with N₂, and 80 g of styrene and 0.8 g of 2,2-azobis(2-methylpropionamidine)dihydrochloride are added thereto. The solution is polymerized at 65° C. for 6 hours under an N₂ atmosphere to obtain a soft particle dispersion. After the polymerization reaction, the soft particle dispersion is filtered through a glass filter to obtain soft particles.

### Evaluation I

The soft particles obtained in Synthesis Examples and Comparative Synthesis Examples are evaluated with respect to a size and a pH-dependent zeta potential.

The size and the pH-dependent zeta potential of the soft particles are measured by using a NanoPartica particle analyzer SZ-100VZ (Horiba, Ltd.). The pH-dependent zeta potentials of the soft particles according to Synthesis Examples and Comparative Synthesis Examples are measured by changing pH of the soft particle dispersions prepared by dispersing them in deionized water within a pH range of 3 to 6.5.

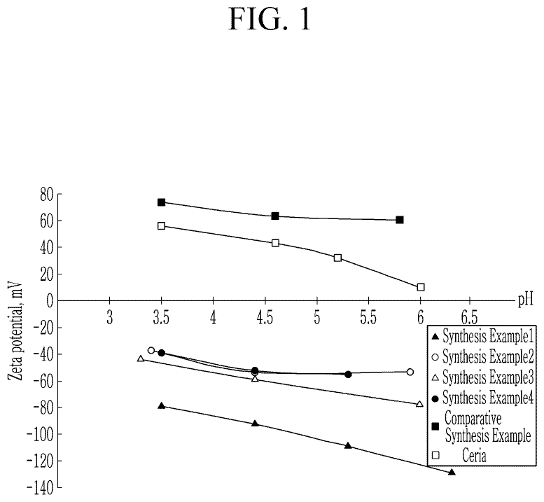

The results are shown in Table 1 and FIG. 1.

FIG. 1 is a graph showing the zeta potential according to pH of the soft particles according to Synthesis Examples and Comparative Synthesis Example.

TABLE 1

| | Average particle diameter of |
|---|---|
| | soft particles (nm) |
| Synthesis Example 1 | 100 |
| Synthesis Example 2 | 300 |
| Synthesis Example 3 | 400 |
| Synthesis Example 4 | 1200 |
| Comparative Synthesis Example 1 | 100 |

Referring to Table 1, it may be confirmed that the soft particles according to Synthesis Examples and Comparative Synthesis Example have an average particle diameter ranging from about 100 nm to 1200 nm.

Referring to FIG. 1, the soft particles of Synthesis Examples exhibit a negative zeta potential in a predetermined pH range (a pH range of soft particle dispersion, for example, a range of 3 to 6.5), and ceria abrasives and the soft particles of Comparative Synthesis Example 1 exhibit a positive zeta potential.

Accordingly, it may be expected that a cleaning slurry may have high dispersion stability due to high electrostatic repulsion between the soft particles and that a strong electrostatic attractive force may act between the soft particles of Synthesis Examples and ceria abrasives.

### Evaluation II

The soft particles of Synthesis Examples are evaluated with respect to fine abrasives adsorption performance.

The fine abrasives adsorption performance is evaluated by adding ceria abrasives (an average particle diameter: about 25 nm, Sigma-Aldrich Co., Ltd.) to the soft particle dispersion (pH=4) obtained by dispersing the soft particles according to Synthesis Examples in deionized water, mixing, and drying them and then, taking a scanning electron microscope (SEM) image.

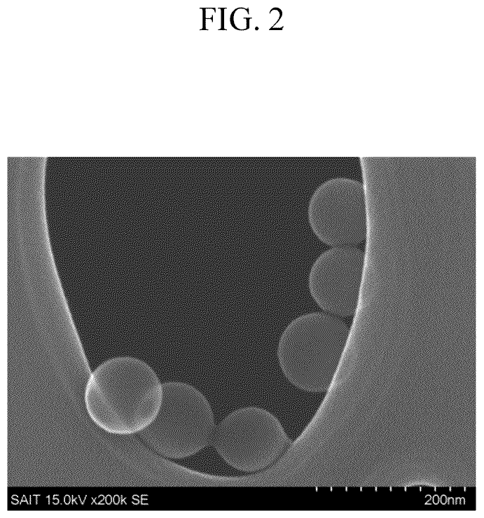

The results are shown in FIGS. 2 to 5.

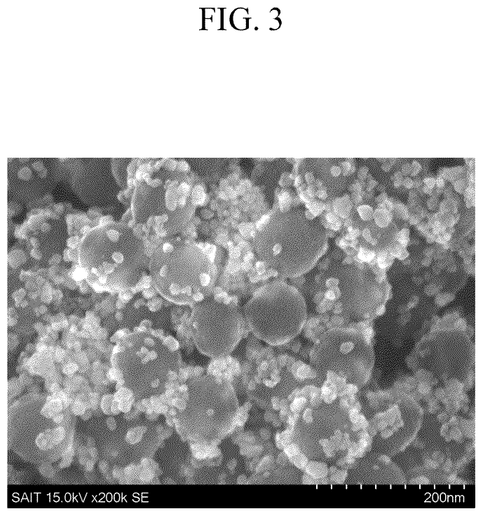

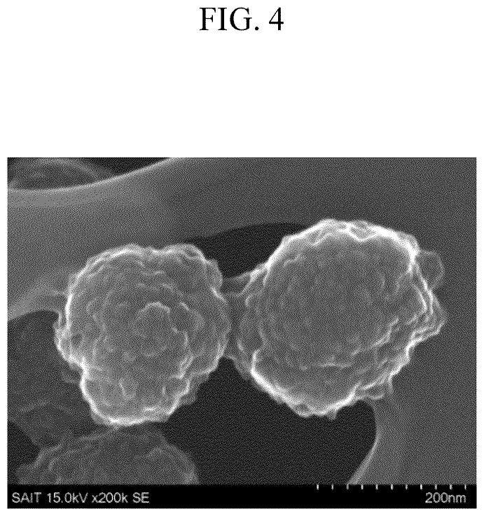

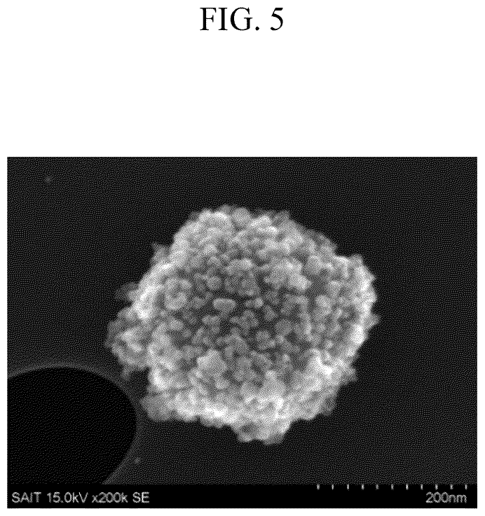

FIG. 2 is an SEM photograph of the soft particles of Synthesis Example 1 before mixing with ceria abrasive, and FIG. 3 is ant SEM photograph showing the soft particles of Synthesis Example 1 and the ceria abrasives adsorbed thereon after mixing them. FIG. 4 is an SEM photograph of the soft particles of Synthesis Example 2 before mixing with ceria abrasive, and FIG. 5 is an SEM photograph showing the soft particles of Synthesis Example 2 with the ceria abrasives adsorbed thereon after mixing the soft particles and the ceria abrasives.

Referring to FIGS. 2 and 3, it may be confirmed that a large amount of the ceria abrasives are adsorbed on the surface of the soft particles according to Synthesis Example 1. Likewise, referring to FIGS. 4 and 5, it may be confirmed that a large amount of the ceria abrasives are adsorbed on the surface of the soft particles according to Synthesis Example 2.

Accordingly, it may be confirmed that there is a sufficient electrostatic attractive force between the soft particles according to Synthesis Examples and the ceria abrasives and that the soft particles according to Synthesis Examples may effectively remove the ceria abrasives from the polished surface.

### Preparation of Cleaning Slurry

### Preparation Example 1

The soft particles according to Synthesis Example 1 are diluted with deionized water to have a solid content of 0.5 wt % to prepare a cleaning slurry. The cleaning slurry is ultrasonicated for 10 minutes. The cleaning slurry does not include a surfactant and other stabilizers.

### Preparation Example 2

The soft particles according to Synthesis Example 2 are diluted with deionized water to have a solid content of 0.5 wt % and then, ultrasonicated for 10 minutes to prepare a cleaning slurry. The pH of the cleaning slurry is adjusted by adding HCl thereto. The cleaning slurry does not include a surfactant and other stabilizers.

### Preparation Example 3

A cleaning slurry is prepared in the same manner as in Preparation Example 1 except that the soft particles according to Synthesis Example 3 are used instead of the soft particles according to Synthesis Example 1.

### Preparation Example 4

Hexagonal boron nitrides (an average particle diameter: about 200 nm) as soft particles are diluted with deionized water to have a solid content of 2.0 wt % to prepare a cleaning slurry. The cleaning slurry is ultrasonicated for 10 minutes before use. The cleaning slurry does not include a surfactant and other stabilizers.

### Preparation Example 5

The soft particles according to Synthesis Example 4 are diluted with deionized water to have a solid content of 0.5 wt % and then, ultrasonicated for 10 minutes to prepare a cleaning slurry. The pH of the cleaning slurry is adjusted by adding HCl thereto. The cleaning slurry does not include a surfactant and other stabilizers.

### Comparative Preparation Example 1

The soft particles according to Comparative Synthesis Example 1 are diluted with deionized water to have a solid content of 0.5 wt % to prepare a cleaning slurry. The cleaning slurry is ultrasonicated for 10 minutes before use. The cleaning slurry does not include a surfactant and other stabilizers.

### Evaluation III

The soft particles included in the cleaning slurries according to Preparation Examples and Comparative Preparation Example are evaluated with respect to a zeta potential.

The zeta potentials of the cleaning slurries are measured by using a Nano Partica particle analyzer SZ-100VZ (Horiba, Ltd.).

The results are shown in Table 2.

TABLE 2

| | pH of cleaning | Zeta potential of soft |
|---|---|---|
| | slurry | particles (mV) |
| Preparation Example 1 | 3.1 | −79.2 |
| Preparation Example 2 | 4.0 | −53.5 |
| Preparation Example 3 | 2.9 | −44.0 |
| Preparation Example 4 | 4.0 | −20.7 |
| Preparation Example 5 | 4.0 | −52.3 |
| Comparative Preparation | 4.0 | +77.5 |
| Example 1 | | |

Referring to Table 2, it may be confirmed that the soft particles included in the cleaning slurry according to Comparative Preparation Example 1 exhibit a positive zeta potential at the pH of the cleaning slurry, but the soft particles included in the cleaning slurries according to Preparation Examples 1 to 5 exhibit a negative zeta potential at the pH of the cleaning slurries.

Accordingly, the cleaning slurries may exhibit high dispersion stability due to high electrostatic repulsion between the soft particles, and a strong electrostatic attractive force may act between the soft particles included in the cleaning slurries according to Preparation Example 1 to 5 and the ceria abrasives.

### Evaluation IV

The soft particles included in the cleaning slurries of Preparation Examples are evaluated with respect to hardness.

The hardness of the soft particles is evaluated by spraying the cleaning slurries according to Preparation Examples onto a wafer with a silicon oxide layer (Mohs Hardness: 6.5) to examine whether the surface of the silicon oxide layer is scratched or not.

The results are shown in Table 3.

TABLE 3

| | Whether scratches occur or not |
|---|---|
| Preparation Example 1 | X |
| Preparation Example 2 | X |
| Preparation Example 3 | X |
| Preparation Example 4 | X |
| Preparation Example 5 | X |

X: No scratches.

Referring to Table 3, it may be confirmed that the cleaning slurries according to Preparation Examples does not generate scratches on the surface of the silicon oxide layer. Accordingly, it may be confirmed that the hardness of the soft particles included in the cleaning slurries according to Preparation Examples is lower than that of the silicon oxide layer.

### EXAMPLES

### Example 1

Colloid ceria abrasives (N10, DITTO) are dispersed in deionized water to prepare a ceria polishing slurry. An average particle size of the ceria abrasives is about 15 nm. Wafers with a silicon oxide layer are chemical mechanical polished by using Bruker-CP4 under the conditions shown in Table 4. Subsequently, the polished wafers are immersed in a ceria polishing slurry for 1 minute, rinsed with deionized water, and dried by a nitrogen flow to prepare contaminated samples. The contaminated samples are cleaned with the cleaning slurry according to Preparation Example 1. The cleaning is performed for 120 seconds using Bruker-CP4 under the same conditions as shown in Table 4 after spraying the cleaning slurry according to Preparation Example 1 onto the same pad (IT-2000, KPX Chemical Co.) as in the CMP process.

### Example 2

Chemical mechanical polishing, preparation of the contaminated samples, and cleaning are performed in the same manner as in Example 1 except that the cleaning slurry according to Preparation Example 2 is used instead of the cleaning slurry according to Preparation Example 1.

### Example 3

Chemical mechanical polishing, preparation of the contaminated samples, and cleaning are performed in the same manner as in Example 1 except that the cleaning slurry according to Preparation Example 3 is used instead of the cleaning slurry according to Preparation Example 1.

### Example 4

Chemical mechanical polishing, preparation of the contaminated samples, and cleaning are performed in the same manner as in Example 1 except that the cleaning slurry according to Preparation Example 4 is used instead of the cleaning slurry according to Preparation Example 1.

### Example 5

Chemical mechanical polishing, preparation of the contaminated samples, and cleaning are performed in the same manner as in Example 1 except that the cleaning slurry according to Preparation Example 5 is used instead of the cleaning slurry according to Preparation Example 1.

### Example 6

Chemical mechanical polishing, preparation of the contaminated samples, and cleaning are performed in the same manner as in Example 1 except that the cleaning is performed for 60 seconds.

### Example 7

Chemical mechanical polishing, preparation of the contaminated samples, and cleaning are performed in the same manner as in Example 1 except that the cleaning is performed for 30 seconds.

### Example 8

First, 0.2 wt % of ceria particles (Sigma Aldrich Co., Ltd.) are dispersed in deionized water to prepare a ceria polishing slurry. An average particle size of the ceria particles is about 25 nm. Wafers with a silicon oxide layer are immersed in the ceria polishing slurry for 1 minute and then, rinsed with deionized water and dried by a nitrogen flow to prepare contaminated samples. Subsequently, the cleaning slurry according to Preparation Example 1 is used to clean the contaminated samples. The cleaning is performed for 120 seconds using Bruker-CP4 under the same conditions as in the CMP shown in Table 4 after mounting the contaminated samples on the same pad (IT-2000, KPX Chemical Co.) as in the CMP process and spraying the cleaning slurry according to Preparation Example 1 thereon.

### Example 9

Preparation of the contaminated samples and cleaning are performed in the same manner as in Example 8 except that the cleaning is performed for 60 seconds.

### Example 10

Preparation of the contaminated samples and cleaning are performed in the same manner as in Example 8 except that a head pressure of the cleaning is changed as shown in Table 4.

### Example 11

Preparation of the contaminated samples and cleaning are performed in the same manner as in Example 8 except that the cleaning is performed for 60 seconds, and the head pressure of the cleaning is changed as shown in Table 4.

### Comparative Example 1

Preparation of the contaminated samples and cleaning are performed in the same manner as in Example 1 except that deionized water is used instead of the cleaning slurry according to Preparation Example 1.

### Comparative Example 2

Preparation of the contaminated samples and cleaning are performed in the same manner as in Example 1 except that the cleaning slurry according to Comparative Preparation Example 1 is used instead of the cleaning slurry according to Preparation Example 1.

TABLE 4

| | Head | | Platen | | |
|---|---|---|---|---|---|
| | pres- | Head | rotation | Spray | Cleaning |
| | sure | speed | speed | speed | time |
| | (psi) | (rpm) | (rpm) | (ml/min) | (s) |
| Example 1 | 3.5 | 97 | 87 | 120 | 120 |
| Example 2 | 3.5 | 97 | 87 | 120 | 120 |
| Example 3 | 3.5 | 97 | 87 | 120 | 120 |
| Example 4 | 3.5 | 97 | 87 | 120 | 120 |
| Example 5 | 3.5 | 97 | 87 | 120 | 120 |
| Example 6 | 3.5 | 97 | 87 | 120 | 60 |
| Example 7 | 3.5 | 97 | 87 | 120 | 30 |
| Example 8 | 3.5 | 97 | 87 | 120 | 120 |
| Example 9 | 3.5 | 97 | 87 | 120 | 60 |
| Example 10 | 2.5 | 97 | 87 | 120 | 120 |
| Example 11 | 2.5 | 97 | 87 | 120 | 60 |
| Comparative Example 1 | 3.5 | 97 | 87 | 120 | 120 |
| Comparative Example 2 | 3.5 | 97 | 87 | 120 | 120 |

### Evaluation V

The contaminated samples according to Examples and Comparative Examples before and after the cleaning are examined with respect to the surfaces of the contaminated samples.

The surfaces of the contaminated samples before and after the cleaning are measured with respect to surface roughness by using AFM (NX20, Park system Co.).

A concentration of Ce ions on the surfaces of the contaminated samples before and after the cleaning is measured by using an X-ray photoelectron spectrometer (XPS Quantera II, Ulvac-PHI Inc.).

The results are shown in Table 5.

Referring to Table 5, after the cleaning according to Examples, the ceria abrasives are completely removed, and the surfaces (polished surfaces) of the contaminated samples exhibit significantly reduced surface roughness. On the contrary, the cleaning according to Comparative Example 1 using water and the cleaning according to Comparative Example 2 using soft particles having a zeta potential with the same sign as that of the ceria abrasives are confirmed that not only a significant amount of residual ceria abrasives exist, but also the surface (e.g., polished surface) of the contaminated samples exhibit a relatively high surface roughness. Accordingly, it may be confirmed that the cleanings according to Examples are effective for removing the ceria abrasives from the surface (e.g., polished surface) of the contaminated samples.

TABLE 5

| | Average surface roughness | |
|---|---|---|
| | of surface of contaminated | Ce content |
| | samples (R, nm) | (at %) |
| Before cleaning | 2.98 | 5.51 |
| Example 1 | 0.162 | 0 |
| Example 2 | 0.124 | 0 |
| Example 3 | 0.115 | 0 |
| Example 4 | 0.148 | 0 |
| Example 5 | 0.097 | 0 |
| Example 6 | 0.156 | 0 |
| Example 7 | 0.158 | 0 |
| Example 8 | 0.094 | 0 |
| Example 9 | 0.106 | 0 |
| Example 10 | 0.088 | 0 |
| Example 11 | 0.086 | 0 |
| Comparative Example 1 | 0.227 | 1.15 |
| Comparative Example 2 | 0.190 | 0.06 |

While this disclosure has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

What is claimed is:

1. A method for manufacturing a semiconductor device, the method comprising
performing a chemical mechanical polishing on a surface of the semiconductor device using a polishing slurry including abrasives to provide a polished surface, and
conducting a cleaning by supplying a cleaning slurry comprising soft particles and a dispersion medium to remove the abrasives from the polished surface on which the chemical mechanical polishing is performed, the soft particles having a lower hardness than the polished surface,
wherein a zeta potential of one of the soft particles and the abrasives at a pH of the cleaning slurry is greater than 0, and
a zeta potential of the other of the soft particles and the abrasives at the pH of the cleaning slurry is less than 0.

2. The method of claim 1, wherein a difference between a zeta potential of the abrasives and a zeta potential of the soft particles at the pH of the cleaning slurry is greater than or equal to about 20 millivolts.

3. The method of claim 1, wherein a zeta potential of the soft particles at the pH of the cleaning slurry is about −10 millivolts to about −140 millivolts.

4. The method of claim 1, wherein a zeta potential of the abrasives at the pH of the cleaning slurry is about +10 millivolts to about +140 millivolts.

5. The method of claim 1, wherein the pH of the cleaning slurry is in the range of about 2 to about 6.5.

6. The method of claim 1, wherein the polished surface comprises an oxide, a nitride, a carbide, a semiconductor elementary substance, a semiconductor compound, an organic-inorganic compound, a metal, a metal alloy, or a combination thereof.

7. The method of claim 1, wherein the abrasives comprise fine abrasives having a particle diameter of greater than or equal to about 1 nanometer and less than about 50 nanometers.

8. The method of claim 1, wherein the abrasives comprise oxide abrasives, nitride abrasives, carbon abrasives, or a combination thereof.

9. The method of claim 1, wherein the abrasives comprise ceria abrasives.

10. The method of claim 1, further comprising an additional cleaning for removing polishing by-products from the polished surface,
wherein the additional cleaning comprises
supplying a chemical solution for removing the polishing by-product from the polished surface, and
contacting the polished surface in the presence of the chemical solution with a cleaning brush or supplying an ultrasonic wave to the polished surface in the presence of the chemical solution.

11. A method of manufacturing a semiconductor device, the method comprising
performing a chemical mechanical polishing on a surface using a polishing slurry including abrasives to provide a polished surface,
supplying a first cleaning slurry to the polished surface on which the chemical mechanical polishing is performed to remove the abrasives from the polished surface, and
supplying a second chemical solution to the polished surface with the abrasives removed, and contacting the polished surface with a cleaning brush or supplying an ultrasonic wave to the polished surface, each in the presence of the second chemical solution,
wherein the abrasives comprise fine abrasives having a particle diameter of greater than or equal to about 1 nanometer and less than about 50 nanometers,
the first cleaning slurry comprises soft particles and a dispersion medium,
a hardness of the soft particles is lower than that of the polished surface, and
a particle diameter of the soft particles is larger than that of the fine abrasives.

12. The method of claim 11, wherein the soft particles comprise an organic material, an inorganic material, an organic-inorganic material, or a combination thereof, having negative or positive surface charges.

13. The method of claim 11, wherein the soft particles comprise polymer beads having negative or positive surface charges.

14. The method of claim 11, wherein the soft particles comprise hexagonal boron nitride.

15. A cleaning slurry for a semiconductor device, the cleaning slurry being applied after a chemical mechanical polishing using a polishing slurry comprising abrasives, the cleaning slurry comprising
soft particles comprising organic material, inorganic material, organic-inorganic material, or a combination thereof, having a zeta potential of about −10 millivolts to about −140 millivolts at a pH of the cleaning slurry, and
a dispersion medium.

16. The cleaning slurry of claim 15, wherein a Mohs Hardness of the soft particles is about 1 to about 5.

17. The cleaning slurry of claim 15, wherein a particle diameter of the soft particles is about 30 nanometers to about 2 micrometers.

18. The cleaning slurry of claim 15, wherein a pH of the polishing slurry is about 2 to about 6.5.

19. The cleaning slurry of claim 15, further comprising a pH adjuster.

20. The cleaning slurry of claim 15, wherein an amount of the soft particles is about 0.01 to about 5 weight percent based on the cleaning slurry.
